(19) United States
(12) Patent Application Publication
(10) Pub. No.: US 2024/0112984 A1
(43) Pub. Date: Apr. 4, 2024

(54) METHOD AND STRUCTURE OF FORMING BACKSIDE GATE TIE-DOWN

(71) Applicant: INTERNATIONAL BUSINESS MACHINES CORPORATION, ARMONK, NY (US)

(72) Inventors: Tao Li, Slingerlands, NY (US); Liqiao Qin, Albany, NY (US); Ruilong Xie, Niskayuna, NY (US); Kisik Choi, Watervliet, NY (US)

(21) Appl. No.: 17/936,825

(22) Filed: Sep. 29, 2022

(51) Int. Cl. H01L 23/48; H01L 21/8234; H01L 29/06; H01L 29/417; H01L 29/66; H01L 29/775; H01L 29/786

(52) U.S. Cl. CPC H01L 23/481; H01L 21/823412; H01L 21/823418; H01L 21/823475; H01L 29/0673; H01L 29/41733; H01L 29/66439; H01L 29/66545; H01L 29/775; H01L 29/78696

(57) ABSTRACT

A semiconductor device includes power rails formed in a backside of a wafer. A gate of a first transistor on the wafer is connected to a power rail through a via-to-backside power rail (VBPR) gate contact. A source/drain (S/D) region of a second transistor on the wafer is connected to a power rail through a VBPR S/D contact. The VBPR gate contact partially vertically overlaps a gate cut region between the first transistor and the second transistor.

### BACKGROUND

### Technical Field

The present disclosure generally relates to semiconductor devices, and more particularly, to a structure and method of forming gate tie-downs in semiconductor devices.

### Description of the Related Art

A gate tie-down is a type of semiconductor construction that provides an electrical isolation between two abutted cells without the need for a diffusion break. A diffusion (DIFF) transistor source area is connected to an isolation gate to bias the transistor in an off-state mode. The gate tie-down construction is provided on the frontside of a wafer. Frontside power rails occupy a significant footprint in a lower Back-End-of-Line (BEOL), and when there is a tie-down of a gate to a frontside power rail, there are additional Middle-of-Line (MOL) contacts which increases MOL congestion.

### SUMMARY

According to an embodiment, a semiconductor device includes a power rail formed in a backside of a wafer. A gate of a first transistor on the wafer is connected to the power rail through a via-to-backside power rail (VBPR) gate contact. A source/drain (S/D) region of a second transistor on the wafer is connected to the power rail through a VBPR S/D contact. The VBPR gate contact partially vertically overlaps a gate cut region between the first transistor and the second transistor.

In one embodiment, the VBPR gate contact is adjacent an active (RX) region.

In one embodiment, the gate of the first transistor is a dummy gate tied-down to the backside power rail.

In one embodiment, the dummy gate is a High-K Metal Gate (HKMG).

In one embodiment, a gate of the second transistor is an active gate.

In one embodiment, a backside power distribution network (BSPDN) is connected to the backside power rail.

In one embodiment, a Middle-of-Line (MOL) is connected to the active gate of the second transistor.

In one embodiment, a Back-end-of-line (BEOL) is connected to the MOL connection of the second transistor.

In one embodiment, a carrier wafer is connected to the BEOL.

In one embodiment, a backside power distribution network (BSPDN) is connected to the backside power rail.

In one embodiment, an interlayer dielectric (ILD) fill is arranged at least between a portion of an edge of the BSPDN, the backside power rail and at least a respective shallow trench isolation (STI) connected to the first transistor and/or the second transistor.

According to an embodiment, a method of forming a gate tie-down in a semiconductor device includes forming a via-to-backside power rail (VBPR) gate contact in a frontside of a wafer at an edge of a gate of a first transistor. The VBPR gate contact is filled with a dummy gate material. There are forming operations performed including gate patterning, sacrificial silicon-germanium (SiGe) material removal followed by bottom dielectric isolation (BDI) and gate spacer formation to exposed Si and SiGe nanosheets recess, selective SiGe nanosheets indentation and inner spacer formation, source/drain (S/D) epitaxial growth, an interlayer dielectric (ILD) fill, dummy gate open chemical mechanical planarization (CMP) and a gate cut patterning. The dummy gate material is removed from an opened dummy gate and VBPR gate contact. SiGe nanosheets are selectively released from Si nanosheets and a replacement High-K Metal Gate (HKMG) is formed in place of the dummy gate material. A power rail formed on the backside of the wafer is connected to the VBPR gate contact of the first transistor, and a backside power distribution network (BSPDN) is connected to the backside power rail.

In one embodiment, the HKMG is filled in the VBPR gate contact.

In one embodiment, a middle of line (MOL) S/D and gate contacts and a back end of line (BEOL) interconnect layers are formed.

In one embodiment, a carrier wafer is connected to a top of the BEOL interconnect layers; and for wafer flipping and wafer backside processing.

In one embodiment, the method includes flipping the wafer and removing a substrate.

In one embodiment, the method includes connecting the backside power rail to at least one source/drain (S/D) region of a second transistor by a via-to-backside power rail (VBPR) source/drain (S/D) contact.

In one embodiment, the method includes arranging a via-to-backside power rail (VBPR) gate contact adjacent a continuous RX region on the wafer.

In one embodiment, the method includes arranging the VBPR gate contact to partially vertically overlap a gate cut region between the first transistor and the second transistor.

In one embodiment, the method includes connecting the (VBPR) gate contact to at least one gate of a first transistor.

According to an embodiment, a method of forming a semiconductor device includes forming a backside power rail in a backside of a wafer; connecting a via-to-backside power rail (VBPR) gate contact to at least one gate of a first transistor. At least one via-to-backside power rail (VBPR) source/drain (S/D) contact is connected to at least one S/D region of a second transistor. The VBPR gate contact is arranged to partially vertically overlap a gate cut region between the first transistor and the second transistor.

### BRIEF DESCRIPTION OF THE DRAWINGS

The drawings are of illustrative embodiments. They do not illustrate all embodiments. Other embodiments may be used in addition to or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 shows a semiconductor device having a VBPR gate contact, consistent with an illustrative embodiment.

FIGS. 2A, 2B, 2C and 2D illustrates a top view showing sectioning and cross-sectional views of a semiconductor device having a VBPR gate tie down, consistent with an illustrative embodiment.

FIG. 3 is a flowchart illustrating a method of forming a VBPR gate tie-down in a semiconductor device of consistent with respective illustrative embodiments.

FIGS. 4A, 4B, 4C and 4D illustrate a top view showing sectioning and cross-sectional views of a process flow after nanosheet formation and shallow trench isolation formation of a semiconductor device, consistent with an illustrative embodiment.

FIGS. 5A, 5B, 5C and 5D illustrate a top view showing sectioning and cross-sectional views of forming a VBPR gate tie-down, consistent with an illustrative embodiment.

FIGS. 6A, 6B, 6C and 6D illustrate a top view showing sectioning and cross-sectional views of a lithographic stack stripping, and a dummy gate deposit, consistent with an illustrative embodiment.

FIGS. 7A, 7B, 7C and 7D illustrate a top view showing sectioning and cross-sectional views of after a gate patterning, BDI formation/spacer, inner spacer and S/D epi growth, consistent with an illustrative embodiment.

FIGS. 8A, 8B, 8C and 8D illustrate a top view showing sectioning and cross-sectional views of a dummy gate opening CMP, providing after an interlayer dielectric (ILD) fill, and a gate cut formation, consistent with an illustrative embodiment.

FIGS. 9A, 9B, 9C and 9D illustrate a top view showing sectioning and cross-sectional views of an operation of dummy gate removal and SiGe release, consistent with an illustrative embodiment.

FIGS. 10A, 10B, 10C and 10D illustrate a top view showing sectioning and cross-sectional views after an HKMG formation, consistent with an illustrative embodiment.

FIGS. 11A, 11B, 11C and 11D illustrate a top view showing sectioning and cross-sectional views of a formation of an MOL contact, consistent with an illustrative embodiment.

FIGS. 12A, 12B, 12C and 12D illustrate a top view showing sectioning and cross-sectional views after formation of a BEOL and carrier wafer, consistent with an illustrative embodiment.

FIGS. 13A, 13B, 13C and 13D illustrate a top view showing sectioning and cross-sectional views after performing a wafer flip, consistent with an illustrative embodiment.

FIGS. 14A, 14B, 14C and 14D illustrate a top view showing sectioning and cross-sectional views after an Si substrate removal, stopping on an etch stop layer, consistent with an illustrative embodiment.

FIGS. 15A, 15B, 15C and 15D illustrate a top view showing sectioning and cross-sectional views after the etch stop layer removal, consistent with an illustrative embodiment.

FIGS. 16A, 16B, 16C and 16D illustrate a top view showing sectioning and cross-sectional views after an additional Si substrate removal, stopping on the BDI layer, consistent with an illustrative embodiment.

FIGS. 17A, 17B, 17C and 17D illustrate a top view showing sectioning and cross-sectional views after a backside ILD deposit, consistent with an illustrative embodiment.

FIGS. 18A, 18B, 18C and 18D illustrate a top view showing sectioning and cross-sectional views after a backside power rail formation, consistent with an illustrative embodiment.

### DETAILED DESCRIPTION

### Overview

In the following detailed description, numerous specific details are set forth by way of examples to provide a thorough understanding of the relevant teachings. However, it should be understood that the present teachings may be practiced without such details. In other instances, well-known methods, procedures, components, and/or circuitry have been described at a relatively high level, without detail, to avoid unnecessarily obscuring aspects of the present teachings. It is to be understood that the present disclosure is not limited to the depictions in the drawings, as there may be fewer elements or more elements than shown and described.

In discussing the present technology, it may be helpful to describe various salient terms. In one aspect, spatially related terminology such as “front,” “back,” “top,” “bottom,” “beneath,” “below,” “lower,” above,” “upper,” “side,” “left,” “right,” and the like, is used with reference to the direction of the Figures being described. Since components of embodiments of the disclosure can be positioned in a number of different directions, the directional terminology is used for purposes of illustration and is in no way limiting. Thus, it will be understood that the spatially relative terminology is intended to encompass different directions of the device in use or operation in addition to the direction depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other directions) and the spatially relative descriptors used herein should be interpreted accordingly.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, third, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

In a semiconductor integrated circuit, there may be included parallel fins with ends that are arranged along the adjoining edges of each RX region. Isolation regions may be formed by partial removal of the fins to isolate electrically various devices. An insulating material may be filled in the space where a partial removal of the fins has occurred. Fin arrays may be terminated by dummy gates for epitaxial growth of source/drain regions on portions of fins between dummy gates and active gates. The isolation regions separate active device regions, but consume a significant area of the structure. Single diffusion breaks (SDB) and double diffusion breaks (DDB) reduce the width of isolation regions by terminating opposing fin ends of adjacent RX regions. An SDB may have a lateral width of an isolating material that is less than a width of a single gate structure.

Gate tie-downs have been introduced to overcome some of the issues associated with SDB and DDB. For example, gate tie-downs can save costs by avoiding the use of SDB (SDB involves high aspect ratio edges and dielectric fills) and avoids SDB etch-induced epitaxial damage. A gate tie-down, (sometimes referred to as “continuous RX”) is a patented design construction solution that electrically isolates two abutted cells without using a diffusion break such as SDB. There is no loss of area associated with the using of an SDB or DDB. Gate tie-downs are compact and provide enhanced device performance with a minimal loss of area. The use of a gate tie-down is a way of providing a dummy gate in a continuous RX construction.

Gate contacts connect a gate line to upper metal layers in device designs. Gate contacts may be formed over shallow trench isolation (STI) regions, and the forming of the gate contacts in STI regions can result in a large amount of chip area. Gate tie-down structures may connect a gate contact and a source/drain (S/D) region contact. For example, a gate tie-down structure may result in shorting between the S/D region contact and a silicide region, or the silicide region with a conductive substance of an adjacent gate. The voltage may be turned down to zero volts or a nominal level.

### Example Architecture

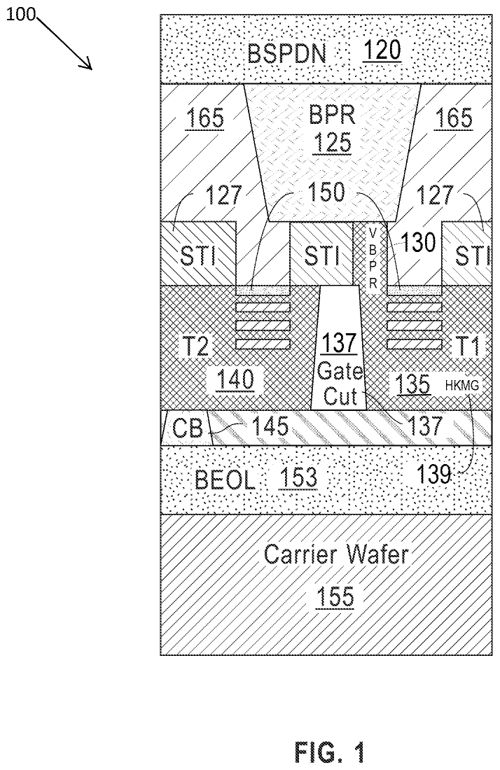

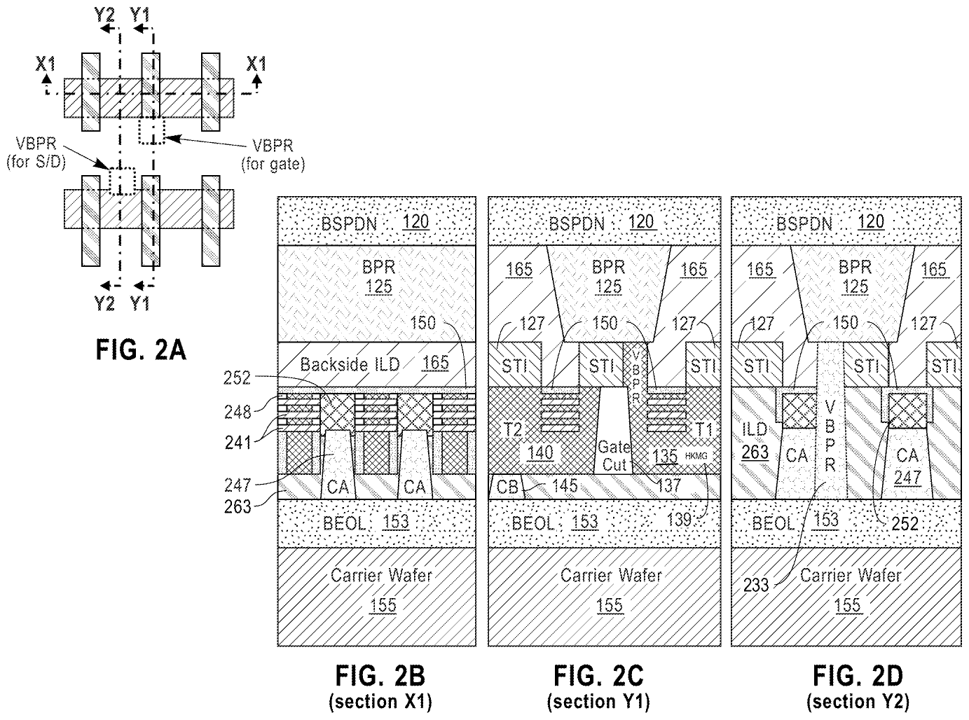

FIG. 1 shows a wafer 100 having a backside tie-down gate arrangement, consistent with an illustrative embodiment. A backside power distribution network (BSPDN) 120 is connected to a backside power rail (BPR) 125 configured to supply power the semiconductor device. The backside power rail 125 is connected to a via-to-backside power rail (VBPR) gate contact 130 that connects the backside power rail 125 to at least one gate 135 of a first transistor T1. A second transistor T2 includes a gate 140 The backside power rail 125 is connected to at least one S/D region 252 (FIG. 2) of the second transistor T2. A shallow trench isolation (STI) 127 is formed for each transistor on the wafer. The VBPR gate contact 130 partially vertically overlaps a gate cut region 137 between the first transistor T1 and the second transistor T2. The gate 135 of the first transistor is a dummy gate tied-down to the backside power rail 125, and the gate 140 of the second transistor T2 is an active gate. The contact CB 145 provides a Middle-End-of-Line (MOL) connection to the gate 140. The backside interlayer dielectric ILD 165 is arranged partially on the bottom dielectric isolation BDI 150. The BDI 150 is a dielectric layer underneath both the source and drain and gate regions. The BDI 150 enhances the operation of the semiconductor by reducing sub-channel leakage and increasing a power performance, as well as provides other benefits.

With continued reference to FIG. 1, there is a Back-End-of-Line (BEOL) 153 and a carrier wafer 155. The BEOL 153 may be a plurality of metal layers that may interconnect devices with wiring layers on the wafer (e.g., the metallization layer). The carrier wafer 155 is bonded to the top of the BEOL 153 and acts as a substrate to enable safe handling and processing during semiconductor fabrication.

### Example Embodiments

FIGS. 2B, 2C and 2D illustrate various cross-sectional views X1, Y1, Y2 with respect to a top view (FIG. 2A), respectively, of semiconductor structure, consistent with an illustrative embodiment. X1 is a cross section in the X direction (see FIG. 2A) showing a backside, and Y1 and Y2 are cross-sections in the Y direction at different positions (as identified in FIG. 2A). A backside power distribution network (BSPDN) 120 is connected to a backside power rail (BPR) 125 configured to supply power the semiconductor device. A via-to-backside power rail (VBPR) source/drain (S/D) contact 233 connects the backside power rail 125 to at least one S/D region 252 of a transistor. The backside power rail 125 is connected to at least one gate 135 of a first transistor T1. A second transistor T2 includes a gate 140. The VBPR S/D contact 233 connects the backside power rail 125 to at least one S/D region 252 of the second transistor T2 (see FIG. 2D).

As shown in FIG. 2C, the VBPR gate contact 130 partially vertically overlaps a gate cut region 137 between the first transistor T1 and the second transistor T2. The gate 135 of the first transistor T1 is a dummy gate tied-down to the backside power rail 125, and the gate 140 of the second transistor T2 is an active gate. The contact CA 247 connects to the S/D region 252, and contact CB 145 provides a middle of line (MOL) connection to the gate 140. With continued reference to FIG. 2, there is a back end of line (BEOL) 153 and a carrier wafer 155. The BEOL 153 may be a plurality of metal layers that may interconnect devices with wiring layers on the wafer (e.g., the metallization layer). The carrier wafer 155 is bonded to the top of the BEOL 153 and acts as a substrate to enable safe handling and processing during semiconductor fabrication. The bottom dielectric isolation (BDI) 150 is a dielectric layer underneath both the source and drain gate regions. The BDI 150 enhances the operation of the semiconductor by reducing sub-channel leakage and increasing a power performance, as well as provides other benefits. The S/D regions 252, and BDI regions 150 are shown, along with the nanosheet channels 241 and inner spacer 248 regions. An interlayer dielectric (ILD) 263 fill is shown partly abutting the BEOL 153.

### Example Process

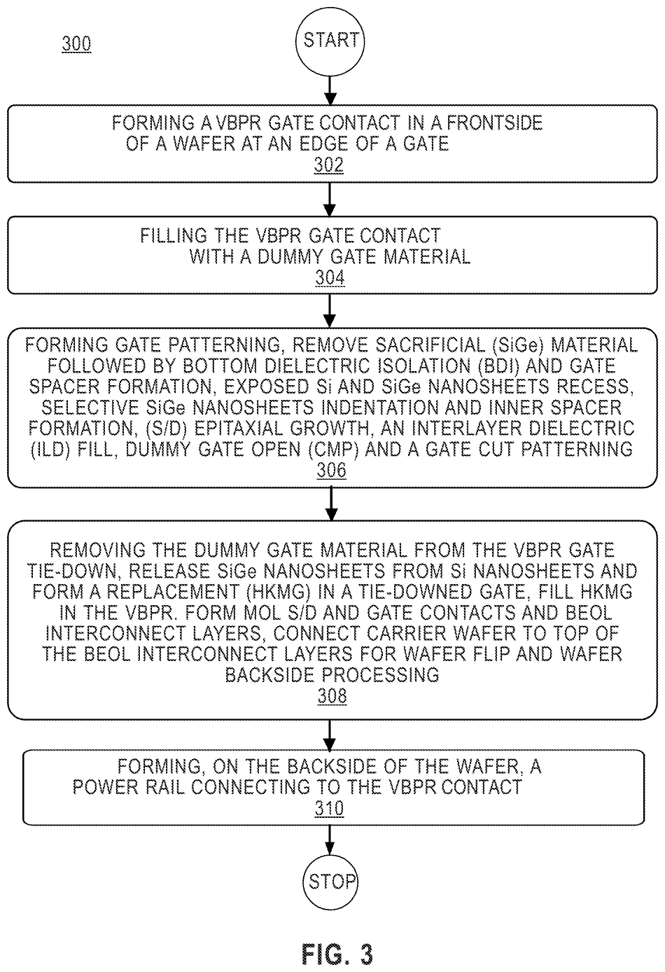

With the foregoing overview of the example architecture, it may be helpful now to consider a high-level discussion of an example process. To that end, FIG. 3 is a flowchart illustrating a method of forming a gate tie-down in a semiconductor device, consistent with respective illustrative embodiments.

FIG. 3 is shown as a collection of blocks, in a logical order, which represents a sequence of operations that can be implemented in hardware, software, or a combination thereof. In each process, the order in which the operations are described is not intended to be construed as a limitation, and any number of the described blocks can be combined in any order and/or performed in parallel to implement the process.

At operation 302, a VBPR gate contact is formed in a frontside of a wafer at an edge of a gate. It is to be understood that operation 302 may be performed with a nanosheet device, but is not limited any particular kind of devices. On a substrate, multiple transistors may be formed. At least a respective shallow trench isolation (STI) is formed for each transistor. The gate tie-down via is formed in a portion of the nanosheet, and some of the STI is etched off.

At operation 304, the VBPR gate contact is filled with a dummy gate material. This operation may include, for example, an lithographic stack strip, hard mask (HM) removal, the application of a dummy gate deposited over the surface of the nanosheet and STI, and dummy gate material deposition.

At operation 306, there is a forming operation of: gate patterning, sacrificial silicon-germanium (SiGe) material removal followed by bottom dielectric isolation (BDI) and gate spacer formation, exposed Si and SiGe nanosheets recess, selective SiGe nanosheets indentation and inner spacer formation, source/drain (S/D) epitaxial growth, an interlayer dielectric (ILD) fill, a dummy gate open chemical mechanical planarization (CMP) and a gate cut patterning.

At operation 308, the dummy gate material is removed from the opened dummy gate and VBPR gate tie-down, SiGe nanosheets are selectively released from the Si nanosheets and a replacement High-K Metal Gate (HKMG) is formed. In a tie-downed gate, the HKMG is filled in the VBPR. Next, middle of line (MOL) S/D and gate contacts and back end of line (BEOL) 153 interconnect layers are formed, followed by carrier wafer 155 connecting to top of the BEOL interconnect layers. The carrier wafer 155 can be bonded to the BEOL 153 interconnect layers to enable the wafer flip and wafer backside processing, including the steps illustrated in the next operation 310.

At operation 310, the wafer is flipped to process the backside and removing a substrate. On the backside of the wafer, power rails are formed connecting to the VBPR gate contact and via-to-backside power rail (VBPR) source/drain (S/D) contact. Next, a backside power distribution/delivery network (BSPDN) is fabricated above, and connected to, the power rail.

With regard to the method described above in the flowchart of FIG. 3, it will be understood that this embodiment is not exhaustive of the scope of the disclosure. For example, the methods may include one or more operations in addition to, or in lieu of, other operations.

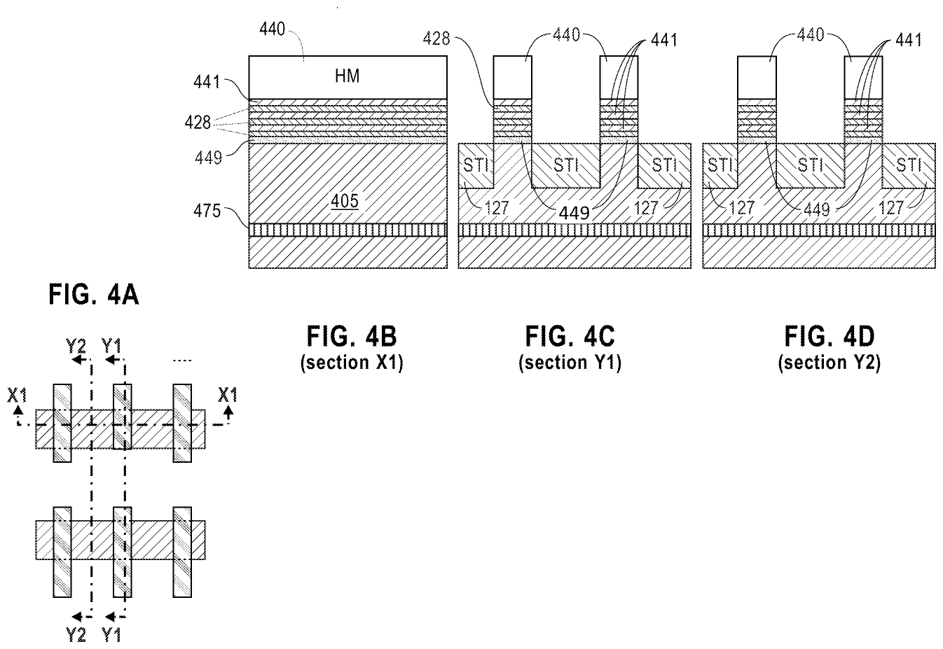

FIGS. 4 through 18 provide additional teachings of a process flow consistent with an illustrative embodiment,

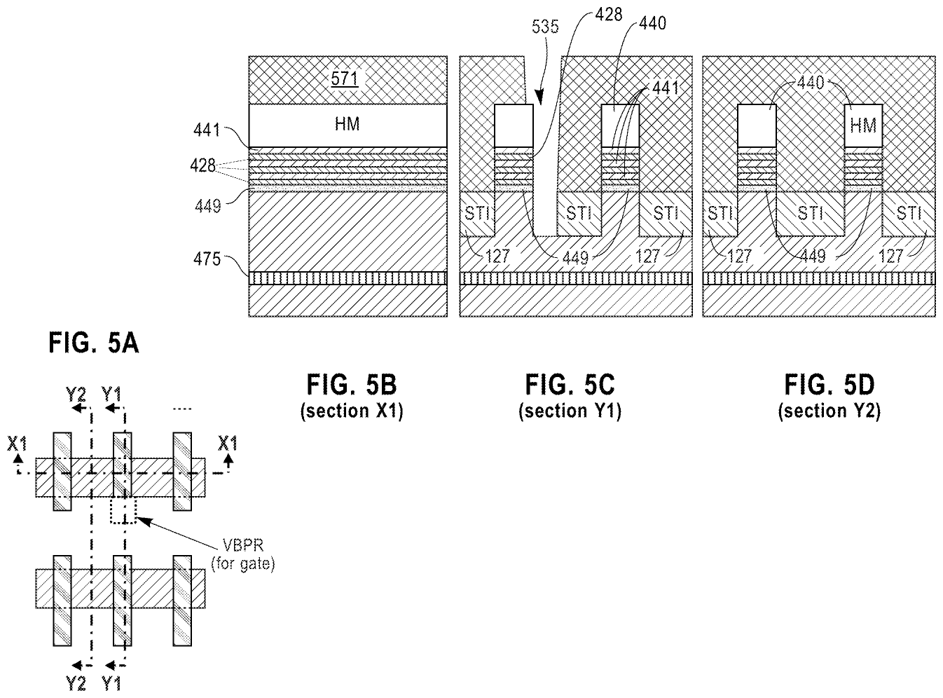

FIGS. 4A, 4B, 4C and 4D illustrate a top view showing sectioning and cross-sectional views of a process flow after nanosheet formation and shallow trench isolation formation of a semiconductor device, consistent with an illustrative embodiment. After nanosheet formation and STI 127 formation, there is shown an substrate 405 with a bottom sacrificial layer of 449 and alternating layers of channel layers 441 and sacrificial layers 428 epitaxially grown. The substrate 405 can be, for example, a material including, but not necessarily limited to, silicon (Si), silicon germanium (SiGe), Si:C (carbon doped silicon), carbon doped silicon germanium (SiGe:C), II-V compound semiconductor or another like semiconductor. The bottom sacrificial layer 449 can be constructed of SiGe, where Ge is in the range of about 45% to 70%. The plurality of channel layers 441 can be constructed of, for example, Si. The plurality of sacrificial layers 428 can be constructed of SiGe, where Ge is in the range of about 15% to 35%. Hard mask (HM) 440 is formed to pattern a film structure (as shown in the top view FIG. 4A). The STI 127 formation is recessed down to the bottom layer of the bottom sacrificial layer 449. An etch stop layer 475 is arranged on the substrate 405. The etch stop layer serves to keep the substrate 405 at certain dimensions that aren't altered by an etching operation. The process continues to FIGS. 5A through 5D.

FIGS. 5A, 5B, 5C and 5D illustrate a top view showing sectioning and cross-sectional views of forming a VBPR gate tie-down, consistent with an illustrative embodiment. A lithographic stack 571 is arranged on top of the HM layer 440 is shown. A via 535 is opened in a portion of the nanosheet (see also FIG. 5A showing top view of the opening marked “VBPR for gate”). FIG. 5C shows a cross-sectional view of the via 535, and it can be seen (when compared with FIG. 4C) that a portion of the STI 127 has been etched off for the subsequent formation of a gate that is connected to the substrate 405.

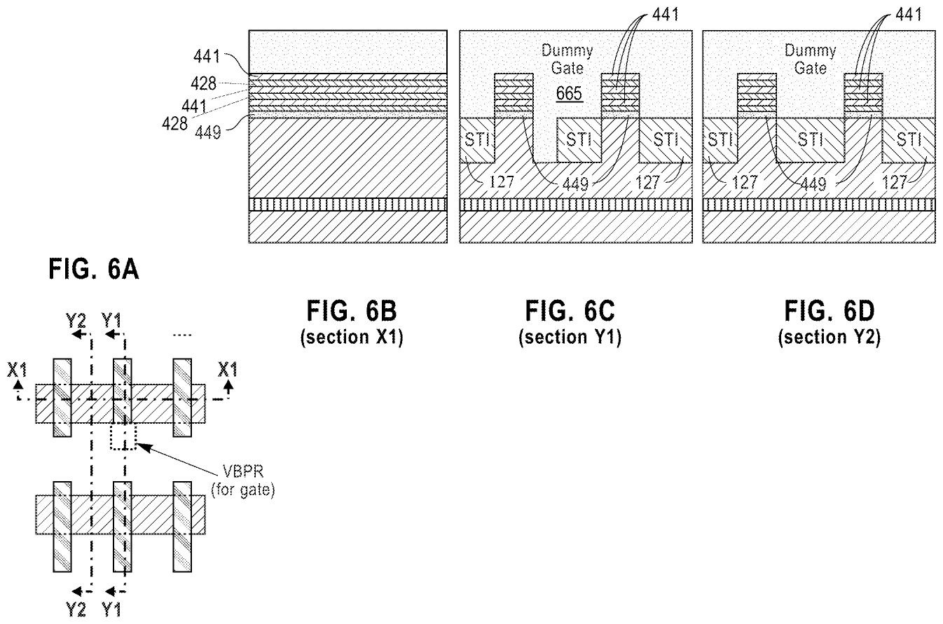

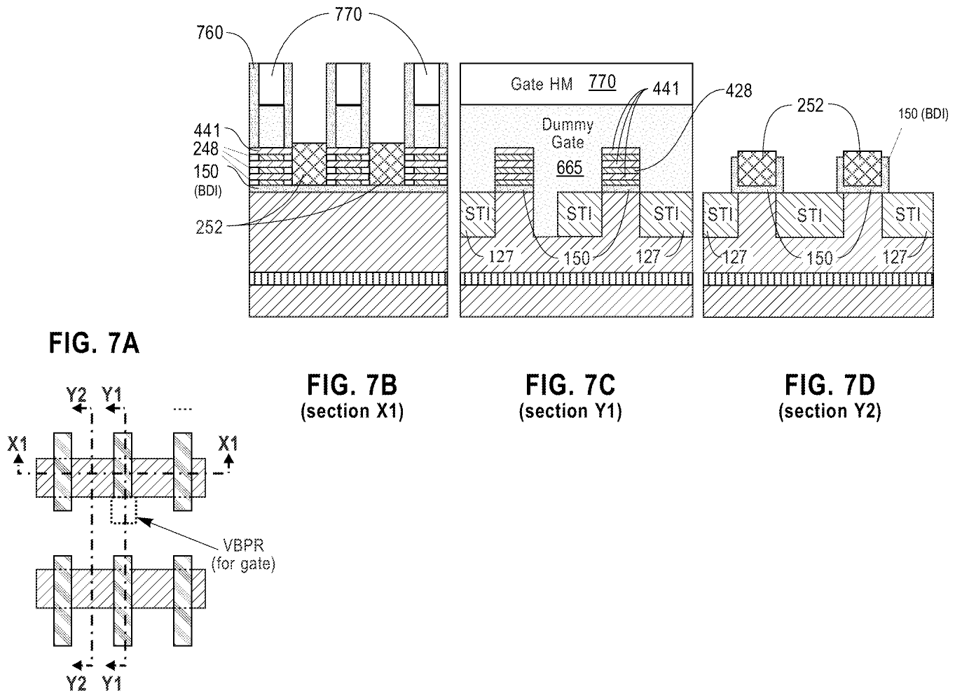

FIGS. 6A, 6B, 6C and 6D illustrate a top view showing sectioning and cross-sectional views of after the lithographic stack 571 (shown in FIGS. 5B-5D) has been stripped, and dummy gate layer 665 has been deposited, consistent with an illustrative embodiment. The dummy gate layer 665 will then be patterned as shown in FIGS. 7A through 7D.

FIGS. 7A, 7B, 7C and 7D illustrate a top view showing sectioning and cross-sectional views of after a gate patterning, bottom sacrificial layer 449 removal, BDI layer 150 and spacer layer 760 formation, inner spacer 248 and S/D epi 252 growth, consistent with an illustrative embodiment. For example, the sacrificial layer 449 is replaced with BDI layer 150 (originally shown in FIG. 1). A gate HM 770 is deposited on the dummy gate 665 for gate patterning. Post gate pattering, the spacer layers 760 are formed along the sidewalls of the dummy gate 665. The bottom sacrificial layer 449 is selectively removed to create a space for the formation of the bottom dielectric isolation layer 150. The bottom sacrificial layer 449 can be selectively removed because of the higher concentration of Ge when compared to the sacrificial layers 428. The bottom dielectric isolation layer 150 is located between the substrate 405 and a bottom layer of the alternating layers of channel layers 441 and sacrificial layers 428. The alternating layers of channel layers 441 and sacrificial layers 428 that are not covered by the dummy gate 665 and gate HM 770 is recessed. and the exposed sacrificial layer 428 is selectively recessed to form the inner spacer 248, and then the S/D epi 252 is formed. It can also be shown in FIG. 7C that the dummy gate layer 665 temporarily fills the via 535 formed (see FIG. 5C).

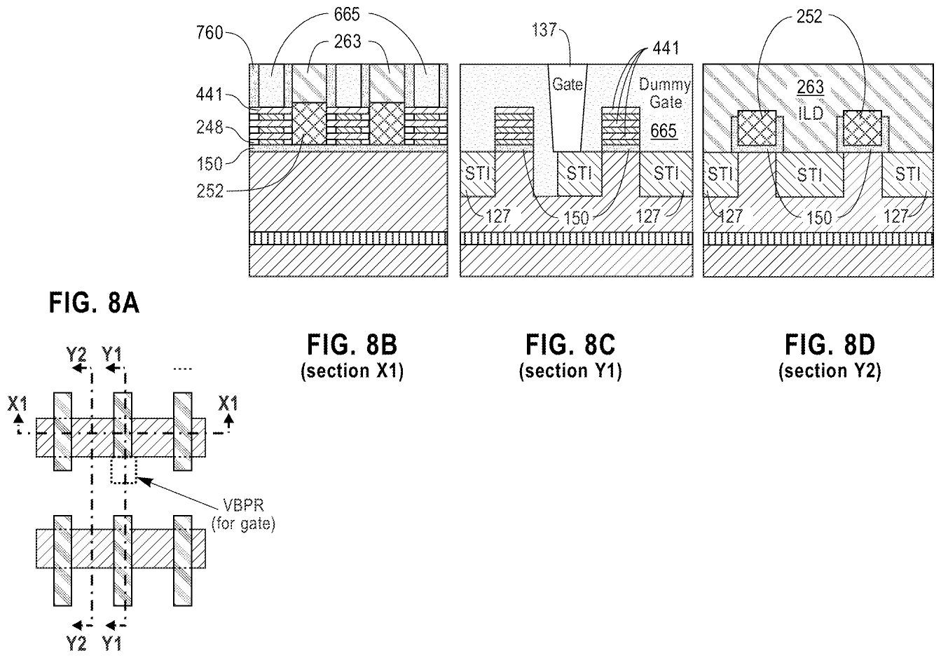

FIGS. 8A, 8B, 8C and 8D illustrate a top view showing sectioning and cross-sectional views of a dummy gate opening CMP 665, providing after an interlayer dielectric (ILD) 263 fill, as well as a gate cut formation, consistent with an illustrative embodiment. The gate cut region 137 is shown in FIG. 8C.

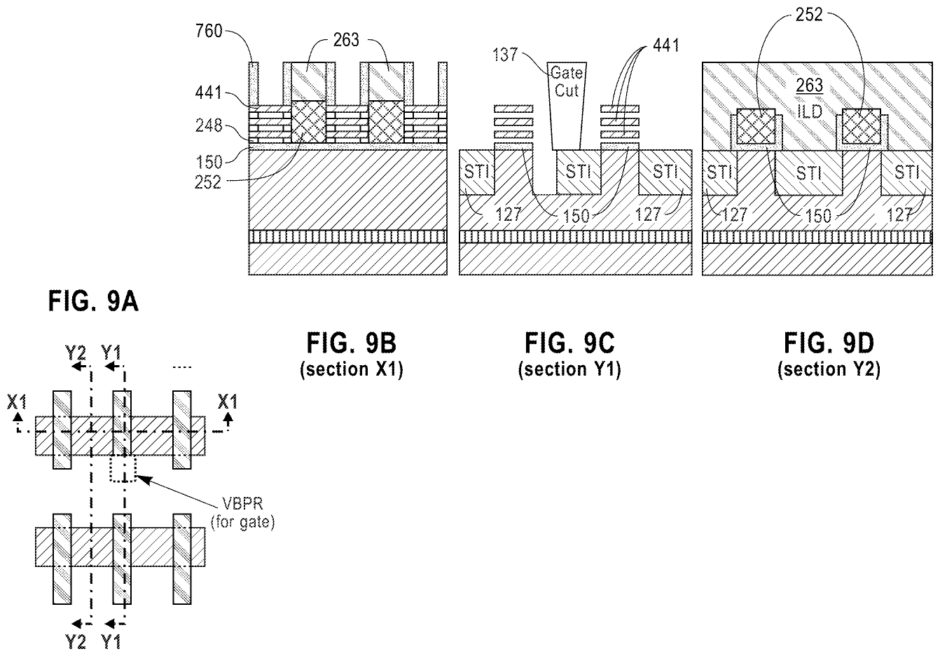

FIGS. 9A, 9B, 9C and 9D illustrate a top view showing sectioning and cross-sectional views of an operation of dummy gate removal and sacrificial layers 428 release, consistent with an illustrative embodiment. The dummy gate 665 of FIG. 8 is removed in FIG. 9. The S/D regions 252, and BDI layer 150 are shown, along with the channel layers 441.

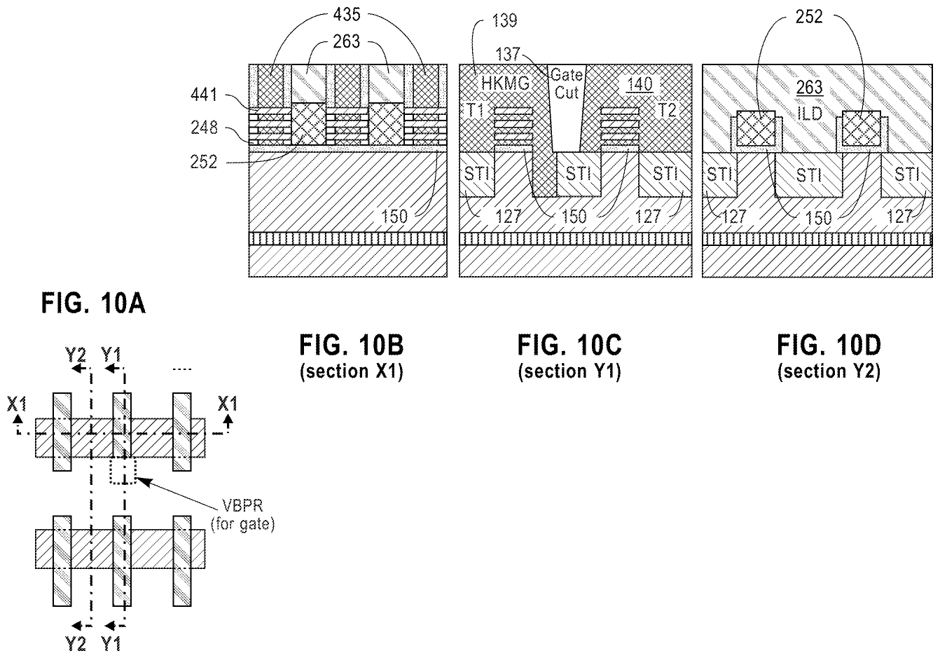

FIGS. 10A, 10B, 10C and 10D illustrate a top view showing sectioning and cross-sectional views after an HKMG formation, consistent with an illustrative embodiment. The HKMG 139 is added to the areas where the dummy gate 665 and the sacrificial layers 428 had been removed in FIG. 9. The BDI layer 150, channel layers 441, and S/D regions 252 are still shown. It is shown that the HKMG extends down to the STI 127 region.

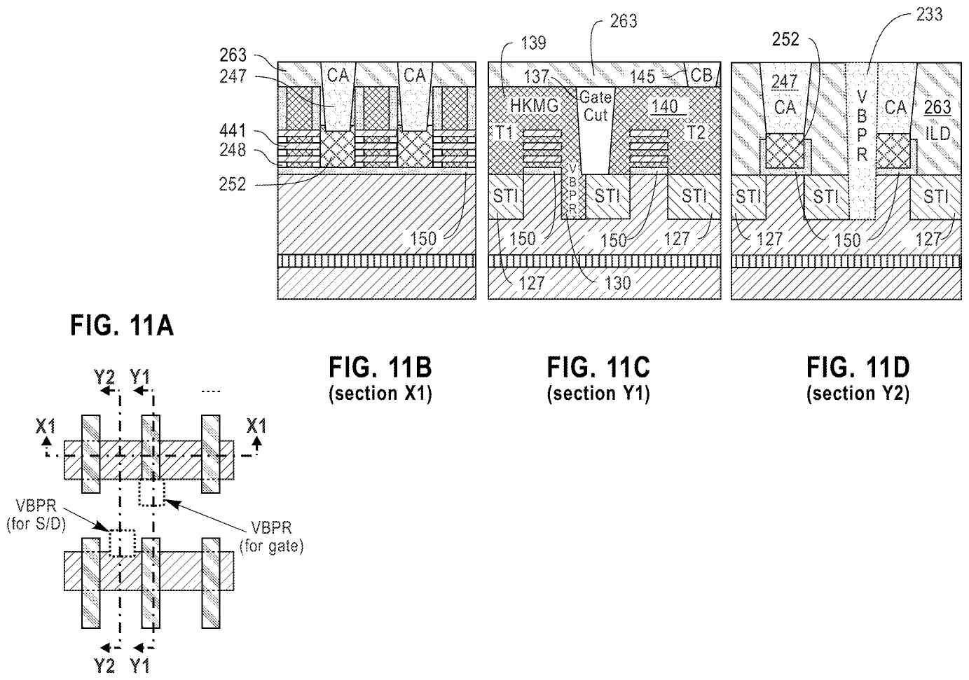

FIGS. 11A, 11B, 11C and 11D illustrate a top view showing sectioning and cross-sectional views of a formation of a MOL contact, consistent with an illustrative embodiment. The S/D contacts 247 are connected with the S/D regions 452. The gate contact 145 contacts the gate 140 (FIG. 11C) and the S/D contact 247 contacts the VBPR 233 (FIG. 11D). The VBPR 233 also contacts the STI 127 region. FIG. 11A shows a top view of the VBPR of the gate (Y1) and the VBPR for the S/D (Y2), in FIGS. 11C and 11D. The ILD 263 fills in upper portions of the structure as shown in the various views of FIGS. 11B, 11C and 11D.

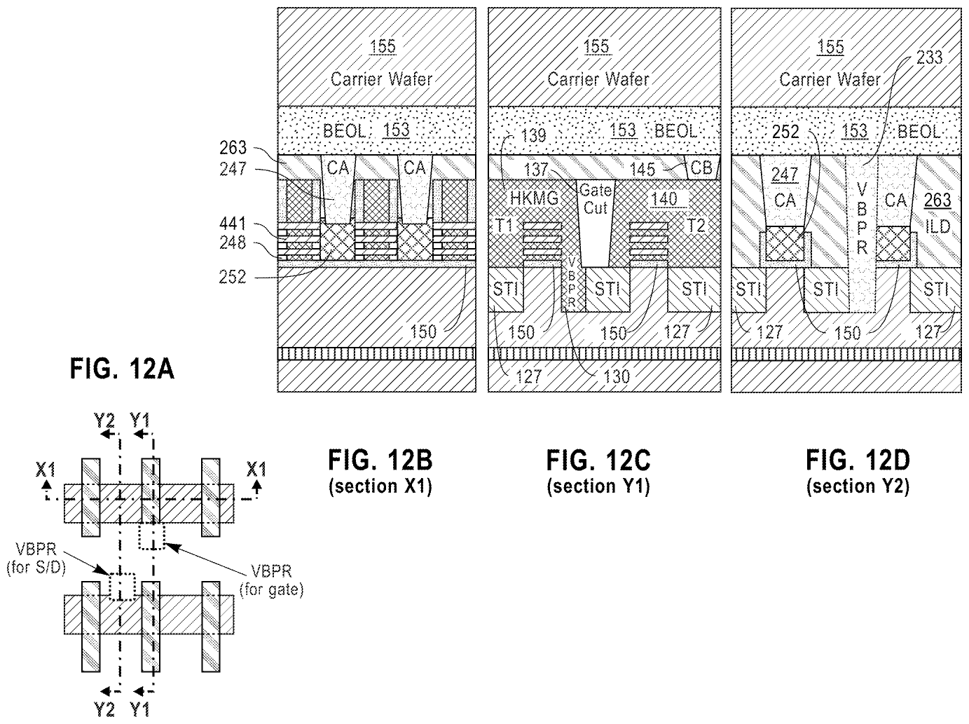

FIGS. 12A, 12B, 12C and 12D illustrate a top view showing sectioning and cross-sectional views after formation of a BEOL and carrier wafer, consistent with an illustrative embodiment. The Back-End of Line (BEOL) 153 are typically metal layers, and the carrier wafer 155 may be bonded to the top of the BEOL 153.

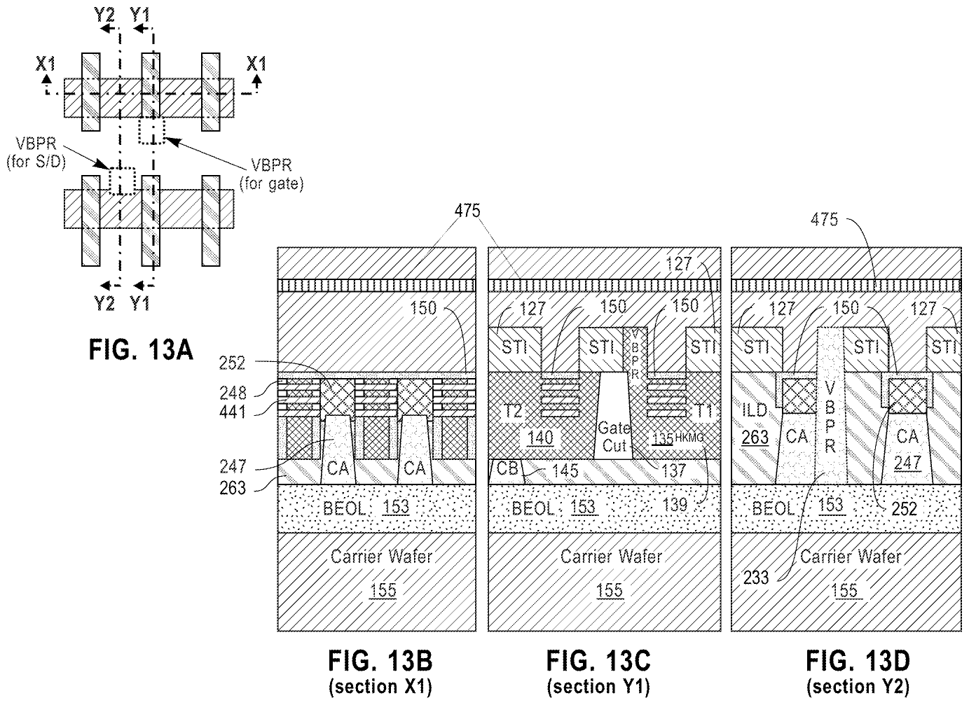

FIGS. 13A, 13B, 13C and 13D illustrate a top view showing sectioning and cross-sectional views after performing a wafer flip, consistent with an illustrative embodiment. It can be seen that the orientations of the carrier wafer 155, BEOL 153, S/D contact 247, gate contact 145, gate cut 137, BDI 150, STI 127, VBPR 130, VBPR S/D contact 233, HKMG 139 and channel layers 441 have changed because of the wafer flip. The wafer flip is performed so that backside processing of the wafer can be performed. After the wafer flip, it can be seen that the substrate layer 405 is on top, here is shown an etch stop layer 475 on which the upper portion of the substrate layer 405 is shown.

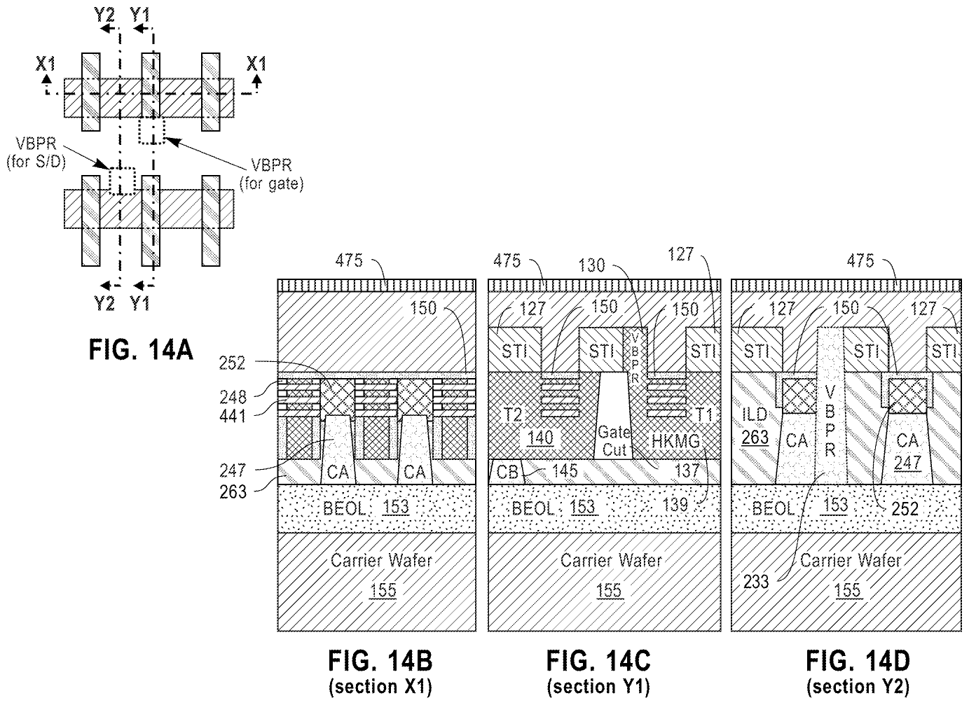

FIGS. 14A, 14B, 14C and 14D illustrate a top view showing sectioning and cross-sectional views after an upper portion of the substrate layer 405 removal, stopping on an etch stop layer, consistent with an illustrative embodiment. The upper portion of the substrate layer has been removed, leaving the etch stop layer 475 at the top. The etch stop layer 475 is used to compensate for any thickness variations in the upper portion of the substrate layer 405 grinding and CMP operations.

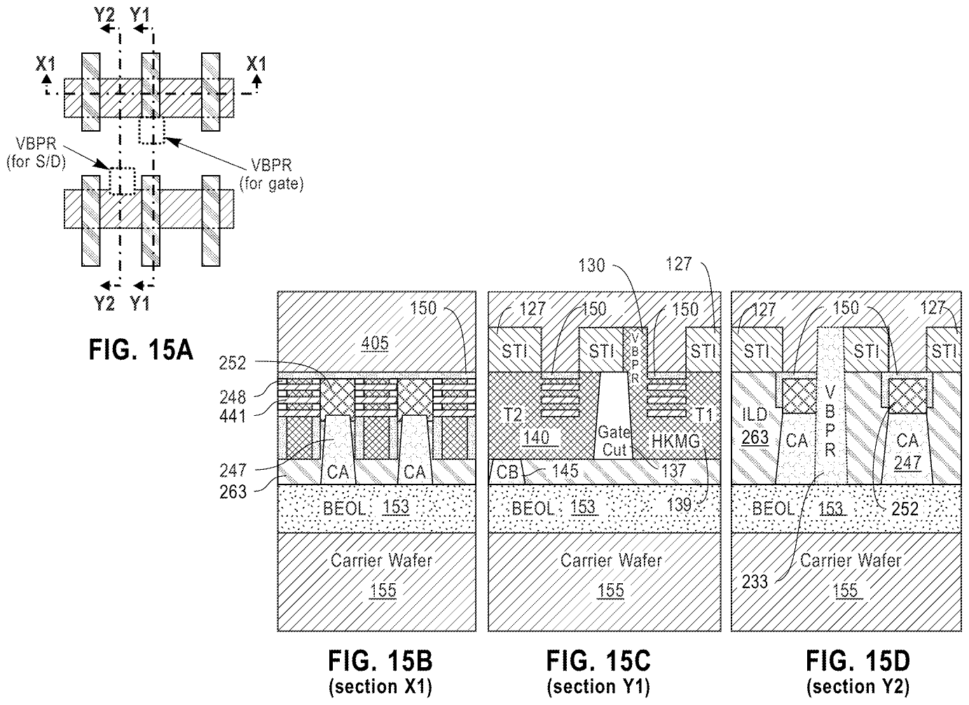

FIGS. 15A, 15B, 15C and 15D illustrate a top view showing sectioning and cross-sectional views after the etch stop layer removal, consistent with an illustrative embodiment. After removal of the etch stop layer 475 (FIG. 14B, 14C, 14D), the depth of the remaining substrate layer 405 should be about the same across the wafer.

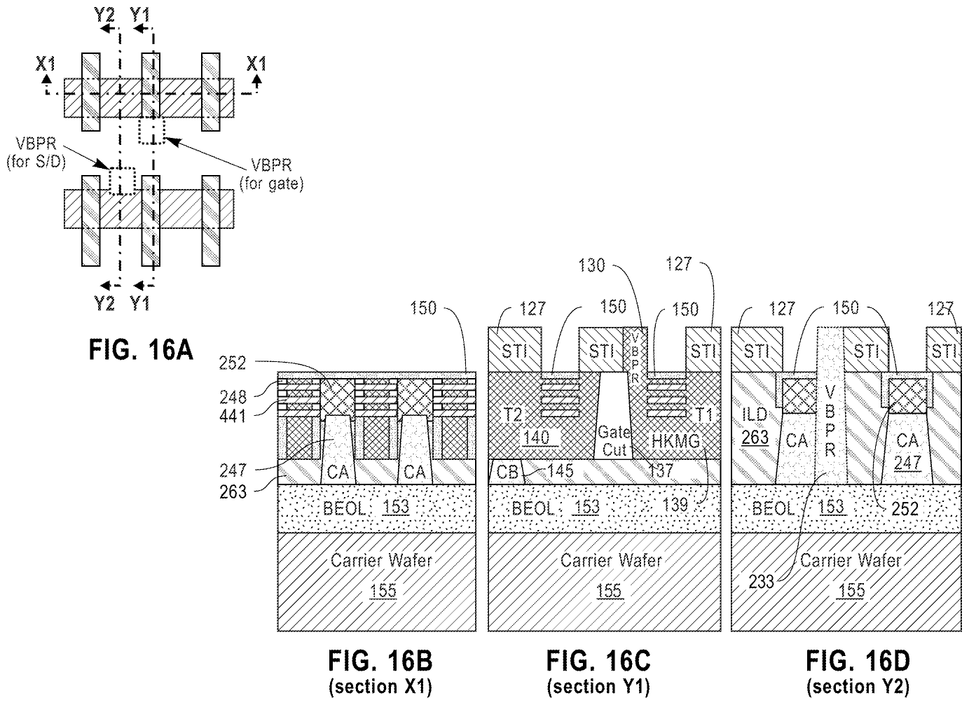

FIGS. 16A, 16B, 16C and 16D illustrate a top view showing sectioning and cross-sectional views after an additional substrate layer 405 removal, stopping on the BDI layer 150, consistent with an illustrative embodiment. The remaining substrate layer 405 (see FIG. 15B through 15D) is completely removed, stopping on the BDI layer 150.

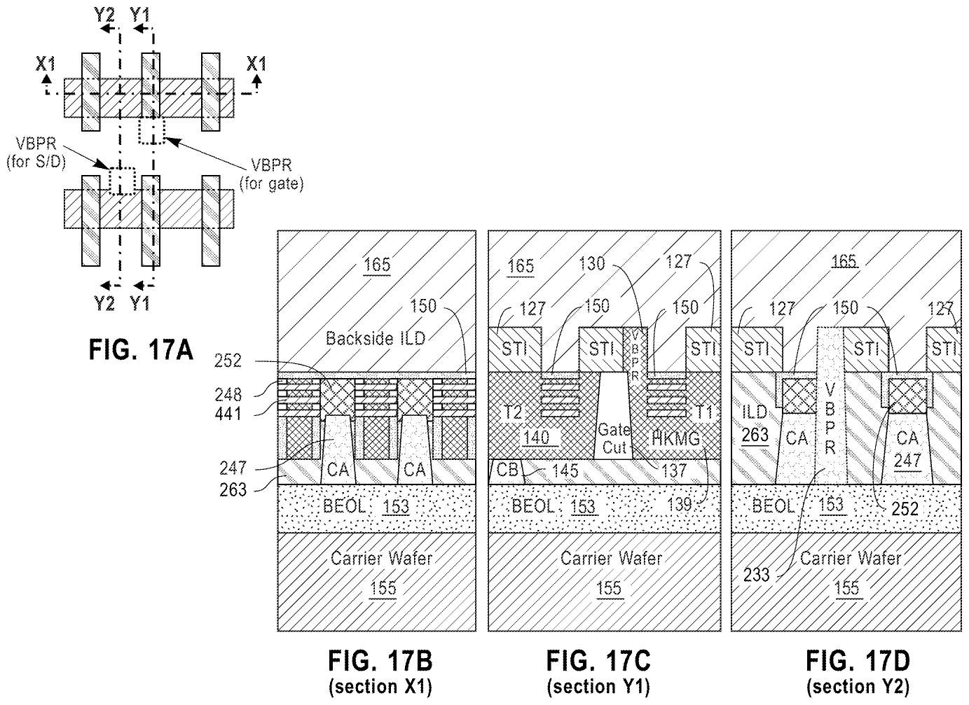

FIGS. 17A, 17B, 17C and 17D illustrate a top view showing sectioning and cross-sectional views after a backside ILD deposit, consistent with an illustrative embodiment. The backside ILD layer 165 is added, as shown in FIGS. 17B through 17D.

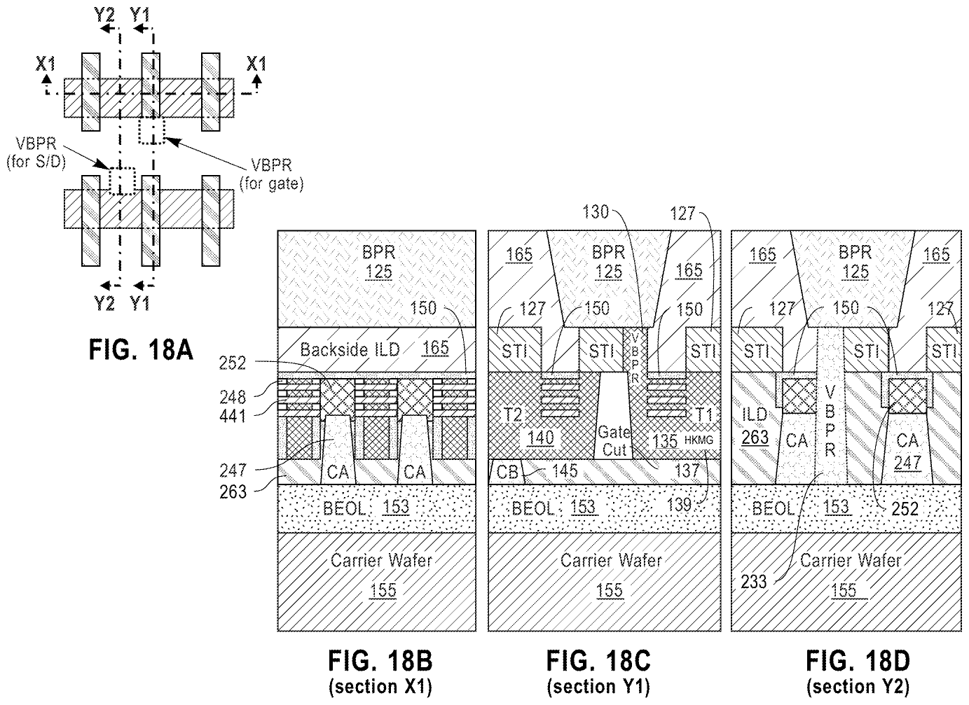

FIGS. 18A, 18B, 18C and 18D illustrate a top view showing sectioning and cross-sectional views after a backside power rail formation, consistent with an illustrative embodiment. It is shown that the backside power rails 125 is arranged such that there is contact with the VBPR gate contact 130 and VBPR S/D contact 233 in FIG. 18D. The gate of T1 135 is tied down by the BPR 125, and is considered to be a dummy gate tied down by the BPR 125. On the other hand, as the gate 140 of T2 is not tied down, it is the active gate.

The finished structure is shown back in FIG. 2, which illustrates the backside power distribution network (BSPDN) 120, consistent with an illustrative embodiment. There may be, in a non-limiting example, about five layers of metal forming the BSPDN 120.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, operations, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

The flowcharts, and diagrams in the figures herein illustrate the architecture, functionality, and operation of possible implementations according to various embodiments of the present disclosure.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any such actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a backside power rail formed in a backside of a wafer;
a via-to-backside power rail (VBPR) gate contact connecting the backside power rail to at least one gate of a first transistor; and
at least one via-to-backside power rail (VBPR) source/drain (S/D) contact configured to connect the backside power rail to at least one S/D region of a second transistor, wherein the VBPR gate contact at least partially vertically overlaps a gate cut region between the first transistor and the second transistor.

2. The semiconductor device according to claim 1, wherein the VBPR gate contact is adjacent an continuous RX region.

3. The semiconductor device according to claim 1, wherein the gate of the first transistor comprises a dummy gate tied-down to the backside power rail.

4. The semiconductor device according to claim 3, wherein the dummy gate comprises a High-K Metal Gate (HKMG).

5. The semiconductor device according to claim 1, wherein a gate of the second transistor comprises an active gate.

6. The semiconductor device according to claim 1, further comprising a Middle-of-Line (MOL) connection to the active gate of the second transistor.

7. The semiconductor device according to claim 6, further comprising a Back-end-of-line (BEOL) connected to the MOL connection of the second transistor.

8. The semiconductor device according to claim 7, further comprising a carrier wafer connected to the BEOL.

9. The semiconductor device according to claim 1, further comprising a backside power distribution network (BSPDN) connected to the backside power rail.

10. The semiconductor device according to claim 9, further comprising an interlayer dielectric (ILD) fill arranged at least between a portion of an edge of the BSPDN, the backside power rail and at least a respective shallow trench isolation (STI) connected to the first transistor and/or the second transistor.

11. A method of forming a gate tie-down in a semiconductor device, comprising:
forming a via-to-backside power rail (VBPR) gate contact in a frontside of a wafer at an edge of a gate of a first transistor;
filling the VBPR gate contact with a dummy gate material;
forming operations including performing gate patterning, a bottom sacrificial layer removal followed by bottom dielectric isolation (BDI) and gate spacer formation to recess exposed alternating layers of channel and sacrificial layers, selective sacrificial layer indentation and inner spacer formation, source/drain (S/D) epitaxial growth, an interlayer dielectric (ILD) fill, dummy gate open chemical mechanical planarization (CMP) and a gate cut patterning;
removing the dummy gate material from an opened dummy gate and VBPR gate contact, tie-down, selectively releasing sacrificial layers from channel layers and forming a replacement High-K Metal Gate (HKMG) in place of the dummy gate material;
forming, on the backside of the wafer, a power rail connecting to the VBPR gate contact, and
connecting a backside power distribution network (BSPDN) to the backside power rail.

12. The method according to claim 11, further comprising, in a tie-downed gate, filling the HKMG in the VBPR gate contact.

13. The method according to claim 12, further comprising forming a middle of line (MOL) S/D and gate contacts and a back end of line (BEOL) interconnect layers;
connecting a carrier wafer to a top of the BEOL interconnect layers; and
bonding the carrier wafer to the BEOL interconnect layers for wafer flipping and wafer backside processing.

14. The method according to claim 12, wherein the forming of the ILD fill is arranged at least between a portion of an edge of the BSPDN, the backside power rail, and at least a respective shallow trench isolation (STI) connected to the first transistor and/or a second transistor.

15. The method according to claim 14, further comprising flipping the wafer to process the backside and removing a substrate.

16. The method according to claim 14, further comprising connecting the backside power rail to at least one S/D region of a second transistor by a via-to-backside power rail (VBPR) source/drain (S/D) contact.

17. The method according to claim 11, further comprising arranging the VBPR gate contact adjacent an continuous RX region on the wafer.

18. The method according to claim 17, further comprising arranging the VBPR gate contact to partially vertically overlap a gate cut region between the first transistor and the second transistor.

19. The method according to claim 17, further comprising connecting the VBPR gate contact to at least one gate of a first transistor.

20. A method of forming a semiconductor device, comprising:
forming a backside power rail in a backside of a wafer;
connecting a via-to-backside power rail (VBPR) gate contact to at least one gate of a first transistor; and
connecting at least one via-to-backside power rail (VBPR) source/drain (S/D) contact to at least one S/D region of a second transistor; and
arranging the VBPR gate contact to at least partially vertically overlap a gate cut region between the first transistor and the second transistor.
